(19) United States
(12) Patent Application Publication
(10) Pub. No.: US 2011/0187451 A1
(43) Pub. Date: Aug. 4, 2011

(54) POWER AMPLIFIER

(75) Inventors: Chul Hwan YOON, Suwon (KR); Seong Geun KIM, Hwaseong (KR); Sang Wook PARK, Suwon (KR); Youn Suk KIM, Yongin (KR)

(73) Assignee: SAMSUNG ELECTRO-MECHANICS CO., LTD., Suwon (KR)

(21) Appl. No.: 13/017,850

(22) Filed: Jan. 31, 2011

(30) Foreign Application Priority Data
Feb. 3, 2010 (KR) 1020100009990

(51) Int. Cl. H03F 3/00; H03F 3/68

(52) U.S. Cl. 330/117; 330/124 R

(57) ABSTRACT

There is provided a power amplifier that can reduce power consumption by selectively turning a plurality of amplifiers on or off according to the power of a signal to be transmitted. A power amplifier according to an aspect of the invention may include: a first amplification section amplifying an input signal by a predetermined gain; a second amplification section having a plurality of amplification units re-amplifying the input signal, amplified by the first amplification section, by predetermined gains; and a switch section supplying or cutting off power to the plurality of amplification units according to an switching signal to selectively operate the plurality of amplification units.

### CROSS-REFERENCE TO RELATED APPLICATIONS

This application claims the priority of Korean Patent Application No. 10-2010-0009990 filed on Feb. 3, 2010, in the Korean Intellectual Property Office, the disclosure of which is incorporated herein by reference.

### BACKGROUND OF THE INVENTION

1. Field of the Invention

The present invention relates to a power amplifier, and more particularly, to a power amplifier that can reduce power consumption by selectively turning a plurality of amplifiers on or off according to the power of a signal to be transmitted.

2. Description of the Related Art

Mobile communications terminals or personal digital assistants have recently come into widespread because they are small, lightweight, thin, and have great portability.

These mobile communications terminals or personal digital assistants transmit or receive radio frequency signals for wireless communications with external devices through antennas.

In order to transmit a signal to an external device, a signal to be transmitted is amplified by a power amplifier so that the amplified signal has desired power, and the amplified signal is then transmitted through an antenna. On the other hand, a signal, received through an antenna, may be amplified by a power amplifier so that the amplified signal has a desired level of power.

The above-described mobile communications terminal or personal digital assistant is supplied with power from an internal power supply, such as a battery, rather than an external power supply, in order to achieve portability, and uses the power to operate internal circuits.

In order to extend the operating time of a mobile communications terminal or a personal digital assistant, the battery capacity thereof needs to be increased. However, an increase in battery capacity is limited since it is associated with an increase in volume of the terminal and portability affected by the volume thereof.

Therefore, the power consumption of the terminal needs to be reduced. In light of the amount of power consumed by the above-described power amplifier, there is a need for a method of reducing the power consumption of the power amplifier.

However, the power amplifier, which is used in the terminal, operates at all times and thus continually consumes power.

### SUMMARY OF THE INVENTION

An aspect of the present invention provides a power amplifier that can reduce power consumption by selectively turning the operations of a plurality of amplifiers on or off according to the power of a signal to be transmitted.

According to an aspect of the present invention, there is provided a power amplifier including: a first amplification section amplifying an input signal by a predetermined gain; a second amplification section having a plurality of amplification units re-amplifying the input signal, amplified by the first amplification section, by predetermined gains; and a switch section supplying or cutting off power to the plurality of amplification units according to an switching signal to selectively operate the plurality of amplification units.

The power amplifier may include a main amplification section having a plurality of main amplification units amplifying signals, obtained by re-amplifying the input signal by the second amplification section, by predetermined gains.

The switch section may supply or cut off power to the plurality of main amplification units of the main amplification section according to the switching signal to selectively operate the plurality of main amplification units.

The power amplifier may further include a coupling section having a plurality of primary windings receiving respective amplification signals from the plurality of main amplification units of the main amplification section, and a secondary winding electromagnetically coupled with the plurality of primary windings and coupling the respective amplification signals from the plurality of main amplification units.

The power amplifier may include an impedance matching section having a plurality of impedance matching units respectively electrically connected between the plurality of amplification units of the second amplification section and the plurality of main amplification units of the main amplification section, the impedance matching section matching impedances of signal transmission paths through which the signals, amplified by the plurality of amplification units of the second amplification section, are respectively transmitted to the plurality of main amplification units of the main amplification section.

The power amplifier may include a variable impedance section varying an impedance of a coupling line of the coupling section according to whether the switch section supplies or cuts off power.

The power amplifier may include a balun converting an unbalanced signal into a balanced signal or converting a balanced signal into an unbalanced signal and inputting the balanced signal or the unbalanced signal to the first amplification section.

The switch section may include a plurality of switches supplying or cutting off the power to the plurality of amplification units and the plurality of main amplification units according to the switching signal.

The variable impedance section may include: a first variable impedance unit varying impedances of the plurality of primary windings according to the switching signal; and a second variable impedance unit varying an impedance of the secondary winding according to the switching signal.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic view illustrating a power amplifier according to an exemplary embodiment of the present invention.

### DETAILED DESCRIPTION OF THE PREFERRED EMBODIMENT

Exemplary embodiments of the present invention will now be described in detail with reference to the accompanying drawings.

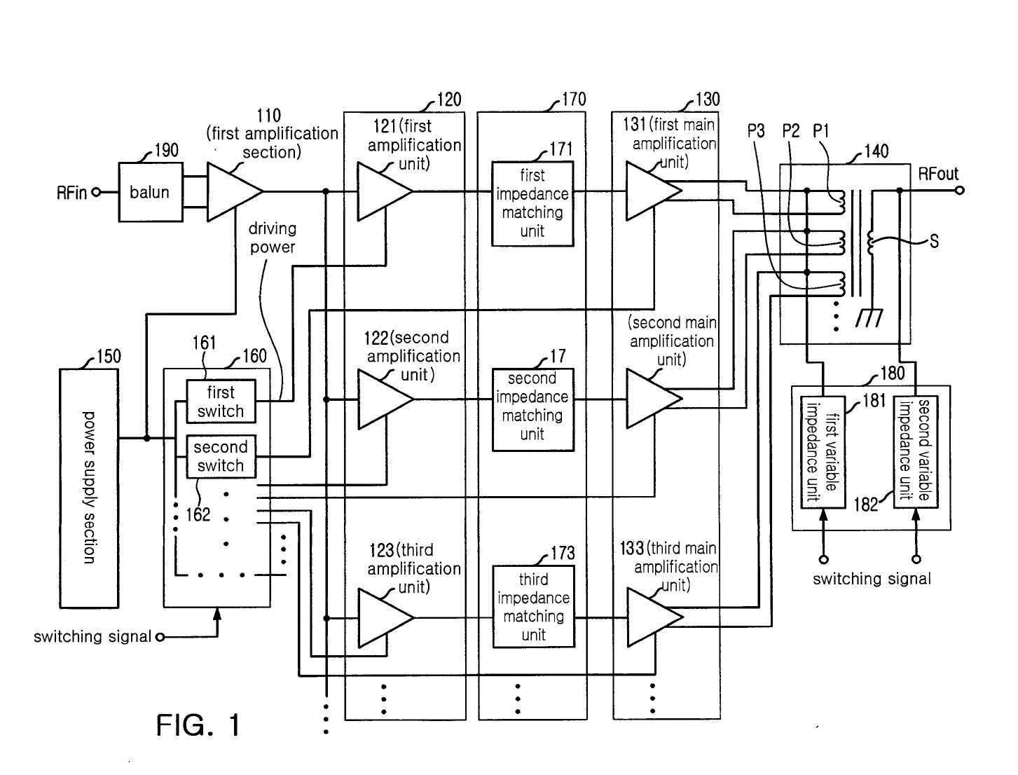

FIG. 1 is a schematic view illustrating the configuration of a power amplifier according to an exemplary embodiment of the present invention.

Referring to FIG. 1, a power amplifier according to this embodiment may include a first amplification section 110, a second amplification section 120, and a switching section 160. The power amplifier may further include a main amplification 130, a coupling section 140, a power supply section 150, an impedance matching section 170, a variable impedance section 180, and a balun 190.

The first amplification section 110 may amplify an input signal by a predetermined gain. Here, the input signal may be a balanced signal. In the balun 190, an unbalanced signal RFin may be converted into a balanced signal, or a balanced signal may be converted in to an unbalanced signal. As such, the unbalanced signal or the above balanced signal may be transmitted to the first amplification section 110 from the balun 190 to a front end of the first amplification section 110.

Plus, the first amplification section 110 may receive driving power, necessary to perform an operation, from the power supply section 150.

The second amplification section 120 may perform a secondary amplification of the signal, amplified by the first amplification section 110.

The second amplification section 120 may include a plurality of amplification units 121, 122, and 123.

The plurality of amplification units 121, 122, and 123 maybe connected in parallel with each other, receive respective signals amplified by the first amplification section 110, and perform the secondary amplification of the signals with predetermined gains.

The plurality of amplification units 121, 122, and 123 operate at the driving power being supplied from the power supply section 150. Here, the switching section 160 controls driving power supply and cutoff to the plurality of amplification units 121, 122, and 123, so that the plurality of amplification units 121, 122, and 123 are selectively driven.

The main amplification 130 may include a plurality of main amplification units 131, 132, and 133.

The plurality of main amplification units 131, 132, and 133 may be connected in parallel with each other, receive the respective signals, re-amplified by the plurality of amplification units 121, 122, and 123 of the second amplification section 120, and amplify a tertiary amplification of the re-amplified signals by predetermined gains.

The plurality of main amplification units 131, 132, and 133 operate at the driving power being supplied by the power supply section 150. The switching section 160 controls power supply and cutoff to the plurality of main amplification units 131, 132, and 133, so that the plurality of main amplification units 131, 132, and 133 are selectively driven.

The coupling section 140 couples the signals, amplified by the plurality of main amplification units 131, 132, and 133 of the main amplification 130, to thereby tertiarily output an output signal Rfout.

The coupling section 140 may include primary windings P1, P2, and P3 and a secondary winding S. Here, the primary windings P1, P2, and P3 may be respectively connected to the plurality of main amplification units 131, 132, and 133, while the secondary winding S may be electromagnetically coupled with the primary windings P1, P2, and P3, so that the signals, subjected to tertiary amplification by the plurality of main amplification units 131, 132, and 133, are coupled, and are subjected to impedance matching, thereby outputting the output signal Rfout.

When the input signal, being supplied to the first amplification section 110, is a balanced signal, both ends of each of the primary windings P1, P2, and P3 may be connected to each of the plurality of main amplification units 131, 132, and 133, while the secondary winding S may have one end outputting the output signal Rfout and the other ,end connected to a ground. On the other hand, though not illustrated in FIG. 1, when the input signal, supplied to the first amplification section 110, is an unbalanced signal, the primary windings P1, P2, and P3 may have one set of ends respectively connected to the plurality of main amplification units 131, 132, and 133 and the other set of ends connected to the ground, and the secondary winding S may have both ends through which balanced signals may be output.

The switching section 160 may selectively supply the driving power from the power supply section 150 to the plurality of amplification units 121, 122, and 123 of the second amplification section 120 and the plurality of main amplification units 131, 132, and 133 of the main amplification 130 according to a switching signal. When the power of a signal to be transmitted from the outside is determined, the switching signal may be transmitted to the switching section 160 so as to operate a corresponding amplification unit. Thus, the switching section 160 may include a plurality of switches including first and second switches 161 and 162. The plurality of switches may respectively correspond to the plurality of amplification units 121, 122, and 123 of the second amplification section 120 and the plurality of main amplification units 131, 132, and 133 of the main amplification 130, thereby control the supplying and cutting-off of the driving power. Furthermore, though not shown in FIG. 1, the plurality of switches 161, 162, and 163 may control the supplying and cutting-off of the driving power to the amplification units and main amplification units having the same signal transmission path at the same time, among the plurality of amplification units 121, 122, and 123 of the second amplification section 120 and the plurality of main amplification units 131, 132, and 133 of the main amplification 130.

The impedance matching section 170 may be electrically connected between the second amplification section 120 and the main amplification 130.

The impedance matching section 170 may include a plurality of impedance matching units 171, 172, and 173. The plurality of impedance matching units 171, 172, and 173 may match the impedances of transmission paths of the signals, which have undergone secondary amplification and are transmitted from the plurality of amplification units 121, 122, and 123 of the second amplification section 120 to the plurality of main amplification units 131, 132, and 133 of the main amplification 130.

The variable impedance section 180 may vary the impedance of the coupling section 140 according to the switching signal. According to the switching signal, the plurality of amplification units 121, 122, and 123 of the second amplification section 120 and the plurality of main amplification units 131, 132, and 133 of the main amplification 130 are selectively operated. For this reason, the coupling section 140 may encounter an impedance mismatch. Therefore, the variable impedance section 180 may include first and second variable impedance units 181 and 182.

The first impedance unit 181 may be selectively connected to the primary windings P1, P2, and P3 of the coupling section 140 according to the switching signal to thereby vary impedance, so that the impedance mismatch can be resolved. In the same manner, the second variable impedance unit 182 may be connected to the secondary winding S of the coupling section 140 according to the switching signal and vary impedance, thereby resolving the impedance mismatch.

As described above, unnecessary power consumption can be reduced by selectively operating amplifiers connected in parallel with each other or blocking operation thereof according to the power of a signal to be transmitted, and multi-stage amplifiers are connected in parallel with each other to improve power calibration, thereby enhancing linear characteristics.

As set forth above, according to exemplary embodiments of the invention, power consumption can be reduced by selectively turning a plurality of amplifiers on or off according to the power of a signal to be transmitted.

While the present invention has been shown and described in connection with the exemplary embodiments, it will be apparent to those skilled in the art that modifications and variations can be made without departing from the spirit and scope of the invention as defined by the appended claims.

What is claimed is:

1. A power amplifier comprising:
a first amplification section amplifying an input signal by a predetermined gain;
a second amplification section having a plurality of amplification units re-amplifying the input signal, amplified by the first amplification section, by predetermined gains; and
a switch section supplying or cutting off power to the plurality of amplification units according to an switching signal to selectively operate the plurality of amplification units.

2. The power amplifier of claim 1, further comprising a main amplification section having a plurality of main amplification units amplifying signals, obtained by re-amplifying the input signal by the second amplification section, by predetermined gains.

3. The power amplifier of claim 2, wherein the switch section supplies or cuts off power to the plurality of main amplification units of the main amplification section according to the switching signal to selectively operate the plurality of main amplification units.

4. The power amplifier of claim 2, further comprising a coupling section having a plurality of primary windings receiving respective amplification signals from the plurality of main amplification units of the main amplification section, and a secondary winding electromagnetically coupled with the plurality of primary windings and coupling the respective amplification signals from the plurality of main amplification units.

5. The power amplifier of claim 2, further comprising an impedance matching section having a plurality of impedance matching units respectively electrically connected between the plurality of amplification units of the second amplification section and the plurality of main amplification units of the main amplification section, the impedance matching section matching impedances of signal transmission paths through which the signals; amplified by the plurality of amplification units of the second amplification section, are respectively transmitted to the plurality of main amplification units of the main amplification section.

6. The power amplifier of claim 4, further comprising a variable impedance section varying an impedance of a coupling line of the coupling section according to whether the switch section supplies or cuts off power.

7. The power amplifier of claim 1, further comprising a balun converting an unbalanced signal into a balanced signal or converting a balanced signal into an unbalanced signal and inputting the balanced signal or the unbalanced signal to the first amplification section.

8. The power amplifier of claim 3, wherein the switch section comprises a plurality of switches supplying or cutting off the power to the plurality of amplification units and the plurality of main amplification units according to the switching signal.

9. The power amplifier of claim 6, wherein the variable impedance section comprises:
a first variable impedance unit varying impedances of the plurality of primary windings according to the switching signal; and
a second variable impedance unit varying an impedance of the secondary winding according to the switching signal.
